(19) United States
(12) Patent Application Publication
(10) Pub. No.: US 2004/0221211 A1
(43) Pub. Date: Nov. 4, 2004

(54) Individually adjustable back-bias technique

(76) Inventor: Thomas W. Chen, Fort Collins, CO (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/427,617

(22) Filed: Apr. 30, 2003

(51) Int. Cl. G11C 29/00

(52) U.S. Cl. 714/721

(57) ABSTRACT

An individual-well adaptive method of body bias control that mitigates the effects of D2D and WD process variations is shown. It is assumed that p-type transistors are grouped in sections. The bodies of all the p-type transistors within a section are connected to a single n-well. This section size can be small enough to provide fine-granular adjustments to the circuit without having any impact on area overhead. With a small amount of additional circuitry and routing, individual well biases can be intelligently adjusted resulting in closely controlled chip power and performance. Experimental results show that binning yields as low as 17% can be improved to greater than 90% using the proposed method.

### CROSS-REFERENCE TO RELATED APPLICATIONS

This application is related to Application No. xx/xxx,xxx also entitled, “An Individually Adjustable Back-Bias Technique,” filed on or about the same date as the present application, and hereby incorporated herein by reference. Application No. xx/xxx,xxx discloses and claims an individually adjustable back-bias technique different from that claimed in the present application.

### FIELD OF THE INVENTION

The present invention relates generally to the field of integrated circuits and more specifically to the field of minimization of the effects of die-to-die (D2D) and within-die (WD) process variations within integrated circuits.

### BACKGROUND OF THE INVENTION

As modern CMOS technology is scaled down, the effects of die-to-die and within-die variations are becoming worse. Process variations can be categorized into four tiers, lot-to-lot variations, wafer-to-wafer variations, die-to-die variations, and within-die variations. For high performance VLSI chips, die-to-die and within-die variations have a significant impact on their performance and power consumption. Even though significant advances have been made to reduce process variations, silicon manufacturers have not been able to keep up with technology scaling. An existing statistical model, assuming a 3σ channel length deviation of 20% for the 50-nm technology generations, indicates that essentially a generation of performance gain can be lost due to systematic within-die variations.

Small variations in spatial dimensions are becoming large relative to the critical dimensions in manufacturing processes. These large relative variations cause wide distributions of circuit operating frequencies and power dissipation. The distributions in frequency and power determine the percentage of circuits or chips, that meet both a minimum frequency, fₜ, and the power dissipation constraint, Pₜ. Given a fixed set of constraints, wider distributions make for lower binning yields after production.

Attempts have been made to adjust n-channel field effect transistor (nfet) and p-channel field effect transistor (pfet) body biases to affect the operating frequency and power consumption, thus, to improve product binning. Researchers beginning in 1995 have discussed the use of adaptive body bias (ABB) to reduce the transistor threshold voltage to retain device performance.

Recent work described an adaptive biasing method using an on-chip measuring circuit to determine the required back bias. Results suggest that, while the simplest implementation of ABB was effective in mitigating the effects of die-to-die (D2D) variation, its effect on within-die (WD) variation was limited. For this approach to be truly effective, V_{nb} (the body voltage of the nfets) needs to be adjusted separately for each section of the circuit, which dictates using a triple-well process to generate both n-wells and p-wells. The effectiveness of this method is further limited by the size of the sections used. Increasing the effectiveness requires adding another power grid section, along with a replica critical path, phase detector, counter, and R-2R ladder digital-to-analog (D/A) converter. This proves to be enormously expensive in both die area and routing resources. Also, localized areas of high variations within a section are not addressed.

### SUMMARY OF THE INVENTION

An individual-well adaptive method of body bias control (IWABB) that mitigates the effects of D2D and WD process variations is shown. It is assumed that p-type transistors are grouped in sections. The bodies of all the p-type transistors within a section are connected to a single n-well. This section size can be small enough to provide fine-granular adjustments to the circuit without having any impact on area overhead. With a small amount of additional circuitry and routing, individual well biases can be intelligently adjusted resulting in closely controlled chip power and performance. Experimental results show that binning yields as low as 17% can be improved to greater than 90% using the proposed method.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a cross-sectional view of an n-well including two pfets.

FIG. 2 is a schematic of an example embodiment of a back-bias circuit according to the present invention.

FIG. 3 is schematic of another example embodiment of a back-bias circuit according to the present invention.

FIG. 4 is a flowchart of an example embodiment of the intelligent adaptive body-biasing algorithm according to the present invention.

FIG. 5 is a block diagram of an example embodiment of the present invention showing the loading of the best chromosome into the scan chain.

### DETAILED DESCRIPTION

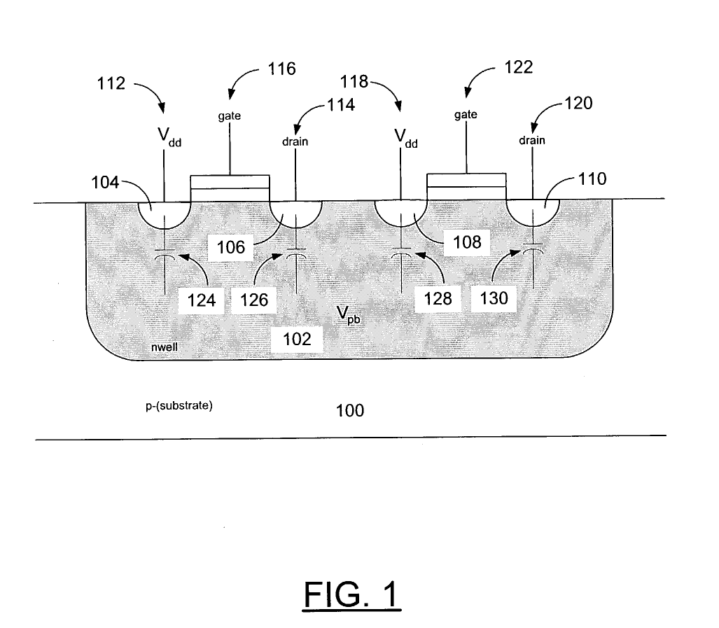

In an n-well or triple-well CMOS process, n-wells (pfet bodies) are normally connected directly to the power supply voltage, V_{dd}. Reducing the pfet body bias reduces their threshold voltage, Vₜ, making the pfets switch faster and increasing their leakage current. Since pfets are inherently slower than nfets, their switching speed is usually one of the limiting factors in overall circuit performance. Increasing pfet speed can provide a significant speed up of the entire circuit. However, instead of using a separate power supply and power grid to control V_{pb} (the body voltage of the pfets) as previous researchers have done, one can use the capacitive coupling between drain and body of the pfets to provide V_{pb} for an entire n-well as illustrated in FIG. 1.

FIG. 1 is a cross-sectional view of an n-well including two pfets. In the example embodiment of the present invention shown in FIG. 1, an n-well 102 is created within a p-substrate 100. Two pfets are shown. A first pfet includes a first source 104 connected to a first source voltage V_{dd} 112, a first drain 106 connected to a first drain voltage 114, and a first gate 116. A second pfet includes a second source 108 connected to a second source voltage V_{dd} 118, a second drain 110 connected to a second drain voltage 120, and a second gate 122. A first source capacitance 124 is shown across the junction between the first source 104 and the n-well 102. A first drain capacitance 126 is shown across the junction between the first drain 106 and the n-well 102. A second source capacitance 128 is shown across the junction between the second source 108 and the n-well 102. A second drain capacitance 130 is shown across the junction between the second drain 110 and the n-well 102.

By disconnecting the n-well from V_{dd} and allowing it to be regulated through these well-to-drain/source capacitors, the body voltage of all the pfets in the n-well will be determined collectively by their collective drain voltage. Assuming an n-well does not contain completely non-inverting logic (i.e., a significant number of pfets in each n-well are conducting at any time), V_{pb} will always be maintained as a voltage somewhat below that of V_{dd}. However, voltage swings of the n-well voltage during pfet switching may create reliability concerns.

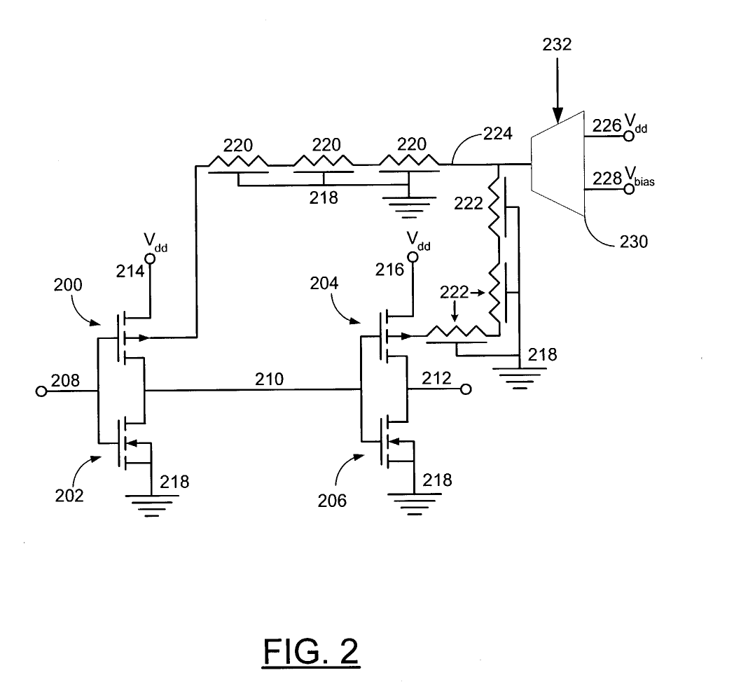

In an example embodiment of the present invention, each individual n-well may be biased to V_{dd} or to a bias voltage V_{bias} as desired. FIG. 2 shows a single n-well containing two inverters, along with the parasitic RC circuits present, and a multiplexer used to select between V_{dd} and the bias voltage V_{bias}.

A first inverter comprising a first pfet 200 and a first nfet 202, is created by connecting the drains of the first pfet 200 and first nfet 202 together, forming a first output node 210. The source of the first pfet 200 is connected to V_{dd} 214, and the source of the first nfet 202 is connected to ground 218. The gates of the first pfet 200 and first nfet 202 are connected together, forming a first input 208. The n-well 224 may be biased to either V_{dd} 226 or a bias voltage V_{bias} 228, as determined by a 2:1 multiplexer 230 controlled through a control line 232, from the output of a scan register not shown in this figure. Those of skill in the art will understand that scan latches, shift registers and other equivalent circuits outputting a control line will fulfill this function within the scope of the present invention. The parasitic resistors and capacitors between the n-well 224 and the first pfet 200 are represented by three RC models 220, connected between the body of the first pfet 200, ground 218, and the n-well 224.

A second inverter comprising a second pfet 204 and a second nfet 206, is created by connecting the drains of the second pfet 204 and second nfet 206 together, forming a second output node 212. The source of the second pfet 204 is connected to V_{dd} 216, and the source of the second nfet 206 is connected to ground 218. The gates of the second pfet 204 and second nfet 206 are connected together, and also connected to the first output 210. The parasitic resistors and capacitors between the n-well 224 and the second pfet 204 are represented by three RC models 222, connected between the body of the second pfet 204, ground 218, and the n-well 224.

The bodies of both pfets in the circuit are connected to the same n-well. The distributed RC trees from the bodies to the multiplexer 230 in FIG. 2 model the parasitics within the well and between the well and the substrate.

Using a 0.1 μm CMOS process and by propagating a switching event through the inverter chain while sweeping the width of the pfets in the inverters independently, one can look at their body bounce and the delay through the chain as a function of the individual inverter widths. This is equivalent to sweeping the number of transistors in the n-well that switch in each direction. Note that sweeping the width of each of the inverters causes the well parasitics to be changed, and such changes are automatically incorporated in the netlist during simulation. There is an increase of about 40 mV in body bounce when the n-well is floating as apposed to that of a normally biased n-well. This should not be of enormous concern in terms of reliability. However, in the example embodiment of the present invention shown here, by actively biasing the n-well to either V_{dd} 226 or V_{bias} 228 this body bounce is greatly reduced. Any n-well can be connected to an active bias voltage of either V_{dd} 226 or V_{bias} 228. Such control requires only one scan latch as shown by the single control line 232 to the multiplexer 230 in FIG. 2. Further, to align the body bounce for the n-wells, one can group the transistors and gates into a single well in such a way that the ratio of the total transistor sizes for switching in one direction versus the other direction is balanced. A ratio less than 2:1 or 3:1 is probably sufficient. Also, note that the bias voltage V_{bias} does not need to be the same for each n-well. Different values of V_{bias} can be used in each n-well if desired.

Since floating wells can only increase power, Pₒₚ (due to increased leakage current), changing the biasing of connected wells is needed in order to reduce overall power dissipation. This can be done in both a single and triple-well process in three ways: (1) the voltage of connected p-wells (substrate in an n-well process) can be lowered, (2) the voltage of connected n-wells can be increased, or (3) both.

During circuit testing the operating frequency, fₒₚ, and power, Pₒₚ, measurements used to bin the chip can first be used to control well connections (i.e., floating or biasing). In order to improve the binning yield, one needs to move the chip into an acceptable region where fₒₚ is greater than or equal fₜ and Pₒₚ is less than or equal to Pₘₐₓ, where fₜ is target frequency and Pₘₐₓ is maximum power. Even for the relatively easy case of allowing floating nwells and p-well biasing, the search space is enormous. For a circuit with n nwells, there are 2ⁿ possible configurations of floating n-wells. Combining this with the range of allowable p-well biases (based on a finite power supply resolution and range) makes an exhaustive search infeasible. However, determining which wells to float can be intelligently done with a genetic method. Each well is assigned to a single bit in a binary chromosome, and the genetic method searches for good combinations of floating and connected wells based on an objective function using fₒₚ, Pₒₚ, fₜ, and Pₜ.

The interactive adjustable body bias (iABB) scheme shown in FIG. 2 adjusts the back body bias for p-channel transistors in n-wells by connecting the body connections of those transistors to a bias voltage V_{bias}. However, the floating body in a different iABB scheme similar to that shown in FIG. 1, may be dragged by the source and drain terminals is such a wide range of voltages that reliability concerns may arise. Thus, by connecting the n-wells to a bias voltage V_{bias} reliability concerns are lessened.

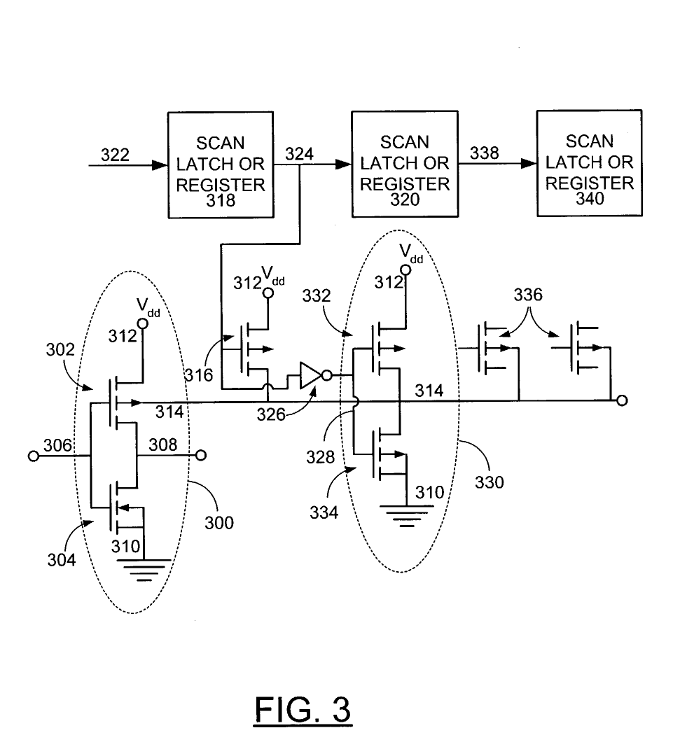

In an example embodiment of the present invention, a voltage divider 330 connected to the local power supply may be used to stabilize the body voltage. FIG. 3 is a schematic representation of an example embodiment of the present invention utilizing a voltage divider. In this example embodiment of the present invention an inverter 300 along with additional p-channel transistors 336 is built within an n-well 314 and the n-well voltage is biased using a voltage divider 330. A first inverter comprising a first pfet 302 and a first nfet 304, is created by connecting the drains of the first pfet 302 and first nfet 304 together, forming a first output node 308. The source of the first pfet 302 is connected to V_{dd} 312, and the source of the first nfet 302 is connected to ground 310. The gates of the first pfet 302 and first nfet 304 are connected together, forming a first input 306. The n-well 314 makes up the body of the first pfet 302, and several additional p-channel transistors 336 are also within the same n-well 314. These additional p-channel transistors 336 are shown unconnected in this example schematic since the connections to their sources, drains, and gates are irrelevant to this embodiment of the present invention. They may be the pfet portions of any type of additional circuitry as desired by the designer using this embodiment of the present invention, and are included here simply for the purpose of showing that there may be a plurality of pfets within the same n-well 314. In this example embodiment, the n-well (bodies of the p-channel transistors) is biased using a p-channel pull-up transistor 316 that is controlled by a scan register output 318. While scan registers are used in this example embodiment of the present invention, those of skill in the art will recognize that scan latches, shift registers, and other equivalent circuits outputting a control line may also be used to perform this function within the scope of the present invention. This scan register 320 may be one of a chain of scan registers, and includes a scan register input 322 and a scan register output 324 connected to other scan registers in the scan chain. The source of the pull-up transistor 316 is connected to the n-well 314 and the drain of the pull-up transistor 316 is connected to V_{dd} 312. Also, the scan register output 318 is connected to the input of an inverter 326, and the inverter output 328 is connected to the input of the voltage divider 330. The voltage divider consists of a third pfet 332 and a fourth pfet 334. The sources of the third and fourth pfets are connected to the n-well 314. The drain of the third pfet 332 is connected to V_{dd} 312 and the drain of the fourth pfet 334 is connected to ground 310. The gates of the third and fourth pfets are connected to the inverter output 328.

The body of the p-channel transistor in the inverter is connected to a pull-up transistor and the output of a voltage divider. When the pull-up transistor is on (the output of the scan register is a zero), the body of the p-channel transistor is connected to V_{dd}. When the output of the scan register is a one, the body voltage of the pull-up transistor is regulated by the voltage divider. Multiple voltage dividers can be placed in parallel to allow a finer granularity of the body voltage adjustment. A single voltage divider circuit can be responsible for a group of p-channel transistors based on their statistical correlation. Also, note that the bias voltage V_{bias} does not need to be the same for each n-well. Different values of V_{bias} can be used in each n-well if desired by varying the construction of the voltage divider. The output of the scan register (or scan latch) is set during the manufacturing testing through a chain of scan registers (or scan latches).

This example embodiment reduces the amount of swing of the body voltages of p-channel transistors as compared leaving the n-wells floating. This reduced swing may improve the potential reliability of the circuit. Also, the steady-state body voltage of p-channel transistors in a given n-well no longer depends on the states of p-channel transistors in the n-well. Rather the steady state body voltage of p-channel transistors in an n-well is determined only by the control asserted to the voltage dividing circuits, eliminating a degree of uncertainty compared to leaving the n-wells floating. Further, this example embodiment of the present invention introduces a possibility of multiple bias voltages to the body of p-channel transistors without having to externally supply them with power, and the associated costs of distributing them. However, this example embodiment of the present invention does incur the cost of the additional circuitry required to implement the voltage dividers.

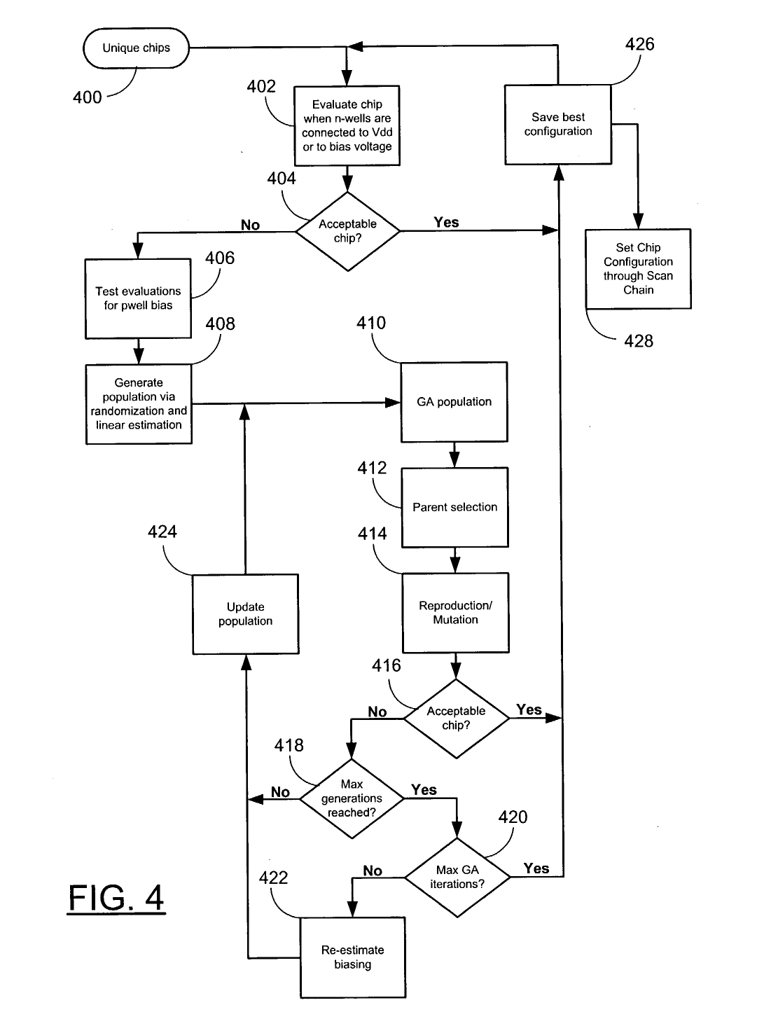

FIG. 4 flowchart of an example embodiment of the Individual Well Adaptive Body Bias (IWABB) method according to the present invention. Given a set of chips with process variations 400, IWABB optimizes each chip based on its specific variations. In a step 402, if the given chip has n n-wells, IWABB is run with an n-bit chromosome where each bit represents a single n-well. Initially, each chip is evaluated twice: once with all n-wells connected to V_{dd} and once with all n-wells connected to a bias voltage. In a decision step 404, if either of these configurations is acceptable, it is saved in a step 426, and the next chip is started. If an acceptable configuration is not found in the initial tests, in a step 406, an evaluation is run to determine the effectiveness of substrate biasing. Using these three evaluations the ΔPₒₚ/Δfₒₚ slope can be determined for both n-well floating and substrate biasing. In a step 408, using a simple linear estimate of the number of floating n-wells and the amount of substrate bias, a random population of chromosomes is generated and evaluated. In a step 410, basic Genitor-style genetic algorithm is run with this initial population. In a step 412, tournament selection is used to select two parent chromosomes from the population. In a step 414, these two parents beget one child chromosome via the reproduction function. The child's floating n-wells are generated by favoring the more fit parent in a HUX-style crossover. The child substrate bias is determined by the average of the parental substrate biasing. The child is then mutated both randomly and based on the average of the two parents. If the average Pₒₚ of the parents is greater than Pₜ, a decrease in substrate bias is favored. If the average fₒₚ of the parents is less than fₜ, the number of floating n-wells is at least the average number of floating parental n-wells. If the average fₒₚ of the parents is greater than fₜ, the number of floating n-wells is at most the average number of floating parental n-wells. This sort of directed mutation is not true to the nature of genetic methods, but helps improve the speed of convergence. In a decision step 416, the child is then evaluated. If it is not acceptable, in a decision step 418, if the maximum number of generations has not been reached, then, in a step 424, the population is updated by replacing the least fit chromosome with the child. The next generation of the genetic algorithm then starts in step 410. If the maximum number of generations have been completed, and, in a decision step 420, the maximum number of Genitor-style genetic algorithm iterations have not been reached, then in a step 422 all of the substrate biases are updated based on a linear estimation. The population is updated in step 424, and the genetic algorithm is then restarted in step 410. At the end of the genetic algorithm iterations as determined by decision step 420, the best chromosome is recorded in a step 426. In a step 428, the best chromosome is used to set the chip configuration through a scan chain.

Those of skill in the art will be familiar with the standard genetic algorithm used in this example embodiment of the present invention. More details on genetic algorithms may be found in David Goldberg, Genetic Algorithms, Addison-Wesley, 1989.

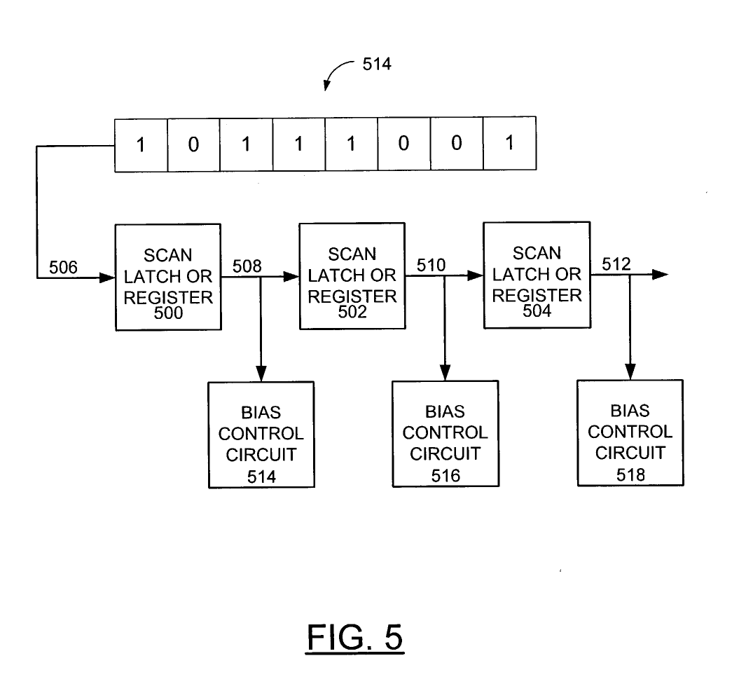

FIG. 5 is a block diagram of an example embodiment of the present invention showing the loading of the best chromosome into the scan chain as shown in step 428 in FIG. 4. A scan chain comprising a first scan latch or scan register 500, a second scan latch or scan register 502, and a third scan latch or scan register 504 is shown. The output 508 of the first scan register 500 is connected to the input of the second scan register and the multiplexer control line of a first bias control circuit 514. The output 510 of the second scan register 502 is connected to the input of the third scan register 504 and the multiplexer control line of a second bias control circuit 516. The output 512 of the third scan register 504 is connected to the multiplexer control line of a third bias control circuit 518. The scan chain is set through the input 506 of the first scan register 500 with the best chromosome for the chip as determined using the method shown in FIG. 4. Those of skill in the art will recognize that while three scan registers and an 8-bit chromosome are shown in this example embodiment of the present invention, the scan chain and chromosome may be any length desired within the scope of the present invention. Typically each n-well on the chip will include one bias control circuit, controlled by a single bit in the scan chain, and the chromosome will be matched in size to the scan chain. Also, note that in some embodiments of the present invention, it may be beneficial to use more than one scan chain, where each scan chain sets a subset of all of the bias control circuits.

The foregoing description of the present invention has been presented for purposes of illustration and description. It is not intended to be exhaustive or to limit the invention to the precise form disclosed, and other modifications and variations may be possible in light of the above teachings. The embodiments were chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. An integrated circuit, comprising: an n-well;
a first p-channel transistor within said n-well, wherein said n-well forms the body of said first p-channel transistor; and
a multiplexer, controlled by a multiplexer control line, wherein an output of said multiplexer is connected to said n-well, and wherein said multiplexer is configured to bias said n-well to one of two different voltages.

2. The integrated circuit of claim 1, wherein a source and a drain of said first p-channel transistor include parasitic resistances and capacitances to said n-well.

3. The integrated circuit of claim 2, wherein the parasitic resistances and capacitances between the source and drain of said first p-channel transistor and said n-well act to stabilize a voltage of said n-well.

4. The integrated circuit of claim 1, wherein said multiplexer control line is driven by the output of a scan register.

5. The integrated circuit of claim 4, wherein the scan register is part of a scan chain.

6. The integrated circuit of claim 5, wherein the outputs of the scan chain are set during manufacturing testing.

7. The integrated circuit of claim 1, wherein said multiplexer control line is driven by the output of a scan latch.

8. The integrated circuit of claim 7, wherein the scan latch is part of a scan chain.

9. The integrated circuit of claim 8, wherein the outputs of the scan chain are set during manufacturing testing.

10. The integrated circuit of claim 1, wherein said multiplexer control line is driven by the output of a shift register.

11. An integrated circuit, comprising:
a first n-well;
a first p-channel transistor within said first n-well, wherein said first n-well forms the body of said first p-channel transistor;
a first multiplexer, controlled by a first multiplexer control line, wherein an output of said first multiplexer is connected to said first n-well, and wherein said first multiplexer is configured to bias said first n-well to either a power supply voltage or a first bias voltage;
a second n-well;
a second p-channel transistor within said second n-well, where in said second n-well forms the body of said second p-channel transistor; and
a second multiplexer, controlled by a second multiplexer control line, wherein an output of said second multiplexer is connected to said second n-well, and wherein said second multiplexer is configured to bias said second n-well to either a power supply voltage or a second bias voltage.

12. The integrated circuit of claim 11, wherein a source and a drain of said first and second p-channel transistors include parasitic resistances and capacitances to said n-well.

13. The integrated circuit of claim 12, wherein the parasitic resistances and capacitances between the source and drain of said first and second p-channel transistors and said n-well act to stabilize a voltage of said n-well.

14. The integrated circuit of claim 11, wherein said first and second multiplexer control lines are driven by the outputs of scan registers.

15. The integrated circuit of claim 14, wherein the scan registers are parts of a scan chain.

16. The integrated circuit of claim 15, wherein the outputs of the scan chain are set during manufacturing testing.

17. The integrated circuit of claim 14, wherein the scan registers are parts of different scan chains.

18. The integrated circuit of claim 17, wherein the outputs of the scan chains are set during manufacturing testing.

19. The integrated circuit of claim 11, wherein said first and second multiplexer control lines are driven by the outputs of scan latches.

20. The integrated circuit of claim 19, wherein the scan latches are parts of a scan chain.

21. The integrated circuit of claim 20, wherein the outputs of the scan chain are set during manufacturing testing.

22. The integrated circuit of claim 19, wherein the scan latches are parts of different scan chains.

23. The integrated circuit of claim 22, wherein the outputs of the scan chains are set during manufacturing testing.

24. The integrated circuit of claim 11, wherein said multiplexer control line is driven by the output of a shift register.

25. An integrated circuit, comprising:
an n-well;
a first p-channel transistor within said n-well, wherein said n-well forms the body of said first p-channel transistor;
a second p-channel transistor within said n-well, wherein a source of said second p-channel transistor is connected to said n-well, and a drain of said second p-channel transistor is connected to a power supply;
a voltage divider, wherein an output of said voltage divider is connected to said n-well; and
an inverter, wherein an input of said inverter is connected to a gate of said second p-channel transistor, and an output of said inverter is connected to an input of said voltage divider.

26. The integrated circuit of claim 25, wherein said input of said inverter is connected to the output of a scan register.

27. The integrated circuit of claim 26, wherein the scan register is part of a scan chain.

28. The integrated circuit of claim 27, wherein the outputs of the scan chain are set during manufacturing testing.

29. The integrated circuit of claim 25, wherein said input of said inverter is connected to the output of a scan latch.

30. The integrated circuit of claim 29, wherein the scan latch is part of a scan chain.

31. The integrated circuit of claim 30, wherein the outputs of the scan chain are set during manufacturing testing.

32. The integrated circuit of claim 25, wherein said input of said inverter is connected to the output of a shift register.

33. The integrated circuit of claim 25, wherein said voltage divider includes a third p-channel transistor and a fourth p-channel transistor, and wherein a source of said third p-channel transistor is connected to said n-well, and a drain of said third p-channel transistor is connected to a power supply, and a source of said fourth p-channel transistor is connected to said n-well, and a drain of said fourth p-channel transistor is connected to ground.

34. The integrated circuit of claim 25, wherein said voltage divider includes a third p-channel transistor and a fourth p-channel transistor, and wherein a drain of said third p-channel transistor is connected to said n-well, and a source of said third p-channel transistor is connected to a power supply, and a drain of said fourth p-channel transistor is connected to said n-well, and a source of said fourth p-channel transistor is connected to ground.

35. A method, comprising the steps of:
a) selecting an integrated circuit chip;
b) evaluating the chip with all n-wells fully connected to a power supply;
c) evaluating the chip with all n-wells fully connected to a bias voltage;
d) saving a best configuration of the chip if the chip is acceptable with all n-wells fully connected to a power supply, or with all n-wells fully connected to a bias voltage, and jumping to step s);
e) testing the evaluations for acceptable p-well bias;
f) generating a population using randomization and linear estimation;
g) running a Genitor-style genetic algorithm on the population;
h) selecting two parent chromosomes from the population using tournament selection;
i) reproducing a child chromosome from the two parent chromosomes;
j) generating the voltage on the child's n-wells by favoring the more fit parent in a HUX-style crossover;
k) setting the child's substrate bias to the average substrate bias of the parents;
l) mutating the child chromosome both randomly and based on the average of the two parents;
m) evaluating the resulting child chromosome;
n) saving the child configuration of the chip if the evaluation of the child is acceptable, and jumping to step s);
o) updating the population if the maximum number of generations has not been reached, and jumping to step g);
p) saving the child configuration of the chip if the maximum number of genetic algorithms have been run, and jumping to step s);
q) re-estimating the biasing on the child chromosome;
r) updating the population, and jumping to step g); and
s) if more chips are available, selecting a new chip, and repeating steps b) through r).

36. A method, as recited in claim 35, further comprising the steps of:
t) reading the configuration; and
u) setting a scan chain on each chip, using the best configuration.
